(19) United States
(12) Patent Application Publication
(10) Pub. No.: US 2013/0180584 A1
(43) Pub. Date: Jul. 18, 2013

(54) Method For Producing An Emitter Of A Solar Cell And Solar Cell

(71) Applicant: Deutsche Cell GmbH, Freiberg (DE)

(72) Inventors: Andre Rolle, Dresden (DE); Andre Wintrich, Dresden (DE)

(73) Assignee: DEUTSCHE CELL GMBH, Freiberg (DE)

(21) Appl. No.: 13/743,015

(22) Filed: Jan. 16, 2013

(30) Foreign Application Priority Data
Jan. 16, 2012 (DE) 10 2012 200 559.5

(51) Int. Cl. H01L 31/18; H01L 31/0216

(52) U.S. Cl. CPC H01L 31/18; H01L 31/02167
USPC 136/256; 438/57

(57) ABSTRACT

A method of producing an emitter of a solar cell comprising introducing a first dopant into a solar cell substrate through a surface of the solar cell substrate, forming a diffusion barrier layer on the surface of the solar cell substrate which is impenetrable by a second dopant, and arranging the second dopant on the diffusion barrier layer.

### CROSS-REFERENCE TO RELATED APPLICATIONS

This application claims the benefit of the filing date under 35 U.S.C. §119(a)-(d) of German Patent No. 102012200559.5, filed Jan. 16, 2012.

### FIELD OF THE INVENTION

The present invention relates to a method for producing an emitter of a solar cell as well to as a solar cell.

### BACKGROUND

When producing selective emitters by means of laser processing, the issue of the achievable contact resistance being dependent on the quality of phosphorus silicate glass frequently occurs. In standard diffusion processes, a doping source, e.g. phosphorus silicate glass, is deposited on a wafer for a predetermined amount of time and subsequently driven into the wafer. One problem occurring in this process is the fact that the phosphorus concentration in the phosphorus silicate glass is predetermined by the deposition parameters which influence the diffusion profile and specifically the surface concentration. This may lead to too little phosphorus remaining in the layer for laser processing, which makes it impossible to achieve a contact resistance having sufficient quality.

### SUMMARY

The present invention generally relates to an improved method of producing an emitter of a solar cell, wherein a contact resistance having sufficient quality may be configured.

The present invention further generally relates to an improved solar cell having an emitter which comprises a contact resistance having sufficient quality.

One embodiment of the invention provides a method of producing an emitter of a solar cell. Said method comprises introducing a first dopant into a solar-cell substrate through a surface of the solar cell substrate, forming a diffusion barrier layer on the surface of the solar cell substrate which is impenetrable by a second dopant, and arranging the second dopant on the diffusion barrier layer.

Another embodiment of the invention provides a method of producing an emitter of a solar cell. Said method comprises depositing phosphorus on a surface of a solar cell substrate; introducing phosphorus into the solar-cell substrate through the surface of the solar cell substrate with oxygen, said introducing with oxygen simultaneously comprising driving the phosphorus into the solar cell substrate with oxygen and forming a diffusion barrier layer on the surface of the solar cell substrate which is impenetrable by a second dopant, and arranging the second dopant on the diffusion barrier layer.

Yet another embodiment of the invention provides as a solar cell comprising an emitter. Saidemitter comprises a first dopant introduced into a solar cell substrate through a surface of the solar cell substrate, a diffusion barrier layer on the surface of the solar cell substrate which is impenetrable for a second dopant, and the second dopant arranged on the diffusion barrier layer.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a flow chart of a method for manufacturing an emitter of a solar cell.

FIG. 2 shows a solar cell.

FIG. 3 depicts a flow chart of a further method for manufacturing an emitter of a solar cell.

FIGS. 4 to 9, each show a schematic view of a solar cell at different points in time of the method for manufacturing an emitter of a solar cell.

### DETAILED DESCRIPTION OF THE EMBODIMENT(S)

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

The layers and processing steps described below and depicted in the figures are merely exemplary of embodiments of the invention. As recognized by those of ordinary skill in the art, embodiments of the invention may be utilized with any solar cell.

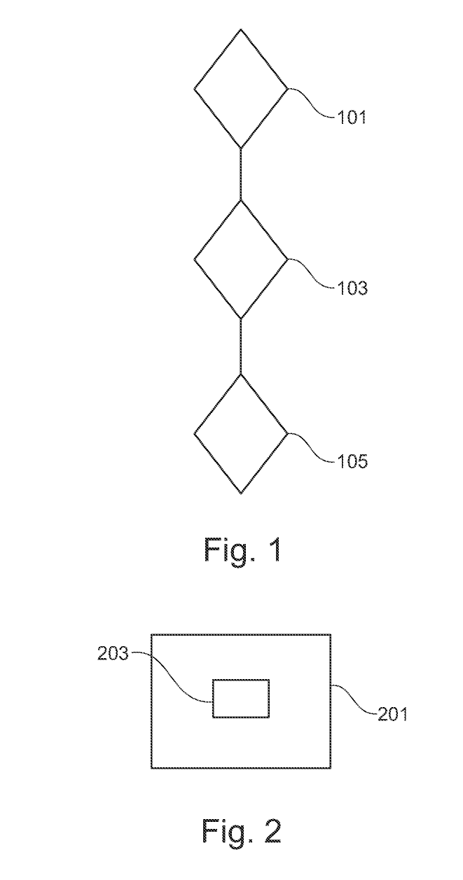

FIG. 1 shows a flow chart of a method for manufacturing an emitter of a solar cell. According to step 101, a first dopant is introduced into a solar cell substrate through a surface of the solar cell substrate. According to step 103, a diffusion barrier layer which is impenetrable by a second dopant is deposited on the surface of the doped solar cell substrate. According to a step 105, the second dopant is deposited on this diffusion barrier layer.

Due to the fact that the diffusion barrier layer is impenetrable for the second dopant, the second dopant may not diffuse through the diffusion barrier layer and into the solar cell substrate in an uncontrolled manner, so that after arranging the second dopant on the diffusion barrier layer a clearly defined amount of the second dopant is available for further steps of processing of the solar cell substrate. Such further processing steps may e.g. comprise the forming of a contact. A further processing step may comprise a laser processing step.

By introducing the first dopant into the solar cell substrate, it is doped in an advantageous manner so that the emitter of the solar cell is formed in the correspondingly doped region. A corresponding contact resistance for an electrical contacting of the emitter may then be effected by means of the second dopant. The method described herein thus comprises two stages: forming a first doped layer in the solar cell substrate and subsequent forming of a second doped layer for an electrical contacting of the emitter.

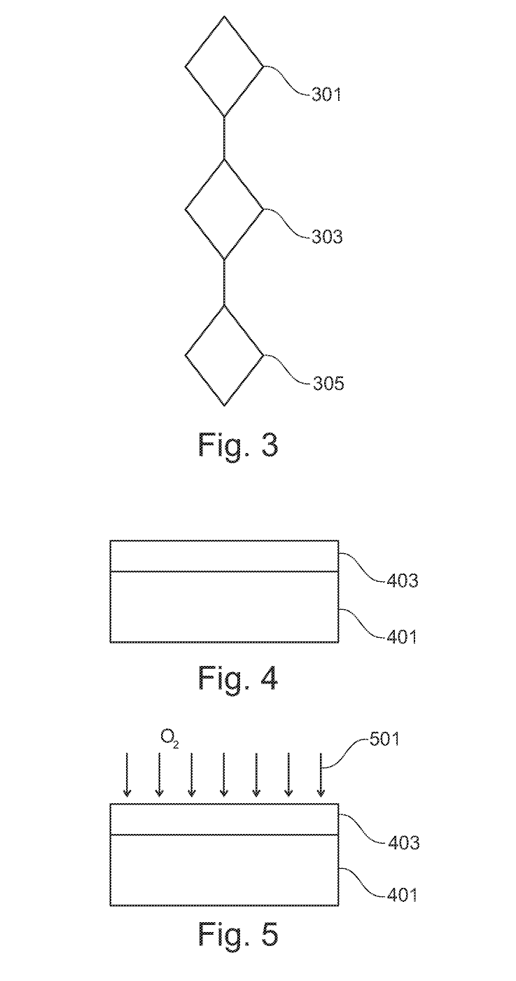

FIG. 2 schematically depicts a solar cell 201 comprising an emitter 203 which was manufactured by means of a method for producing an emitter of a solar cell. For the sake of clarity, possible further elements of the solar cell 201 are not shown herein., no contacts for an electrical contacting of the emitter 203 are shown for clarity's sake.

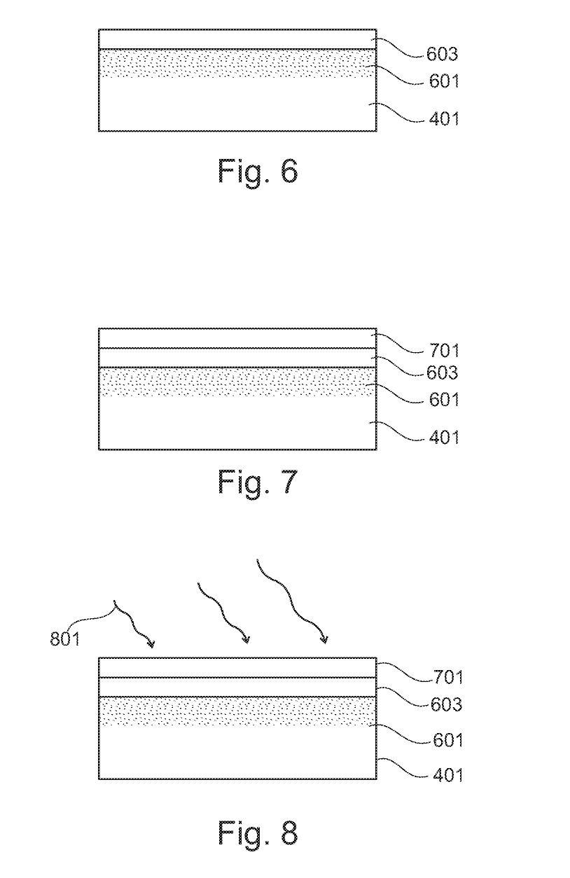

FIG. 3 shows a flow chart of a further method for producing an emitter of a solar cell. The solar cell may in this context e.g. comprise a silicon wafer as a solar cell substrate.

According to step 301, phosphorus silicate glass is deposited on a solar cell substrate using phosphorus oxychloride (POCl) and oxygen. The amount of POCl may preferably be between 500 sccm and 1500 sccm. An amount of oxygen may preferably be between 150 sccm and 800 sccm. A temperature used during step 301 may e.g. be between 730° C. and 860° C. A duration of time of step 301 may preferably be between 5 and 20 minutes.

By depositing the phosphorus silicate glass on the surface of the solar cell substrate, phosphorus is introduced into the solar cell substrate as a first dopant. This means that the solar cell substrate is doped by phosphorus. A layer thickness of the phosphorus silicate glass layer is preferably between 10 nm and 50 nm.

According to step 303 which, with regard to time, may follow immediately upon step 301, the deposited phosphorus silicate glass layer is oxidized with oxygen so that a diffusion barrier layer may be formed in the form of an oxide layer. An amount of oxygen may in this context preferably be between 1000 sccm and 5000 sccm. A temperature during step 303 may e.g. be between 780° C. and 860° C. A duration of time of step 303 may preferably be between 5 and 20 minutes. An oxide layer is preferably formed with a layer thickness between 10 nm and 50 nm. By oxidizing the phosphorus silicate glass layer by means of oxygen, a diffusion layer on the surface of the solar cell substrate is formed which is impenetrable for phosphorus as a second dopant.

According to step 305, phosphorus silicate glass is deposited on the oxidized layer, i.e. the oxide layer or, respectively, the diffusion barrier layer by means of phosphorus oxychloride and oxygen. An amount of POCl may preferably be between 500 sccm and 1500 sccm. An amount of oxygen may e.g. be between 150 sccm and 800 sccm. A temperature set during step 305 may e.g. be between 780° C. and 860° C. A time duration of step 305 may e.g. be between 5 and 20 minutes. The layer thickness of the deposited phosphorus silicate glass layer is preferably between 10 nm and 50 nm.

By again depositing phosphorus silicate glass on the oxide layer, phosphorus is arranged on the diffusion barrier layer, in this case the oxide layer, as the second dopant.

In an embodiment not shown herein, it may be provided that the diffusion barrier layer is opened in order to introduce the second dopant into the solar cell substrate through the aperture or the apertures. Thereby, a contact resistance is formed for an electrical contacting of the emitter, i.e. of the region doped by means of the first dopant of the solar cell. The forming of the aperture in the diffusion barrier layer may preferably be carried out after arranging the second dopant, in this context e.g. phosphorus, on the diffusion barrier layer, in this context the oxidized layer., the aperture is formed by means of laser processing of the diffusion barrier layer. Preferably, the second dopant, in this context phosphorus, is introduced into the solar cell substrate by means of the laser. This means that the diffusion barrier layer, the diffusion barrier layer with the second dopant arranged thereon, is charged by means of laser pulses and/or by means of a continuous laser beam in order to introduce an aperture into the diffusion barrier layer and/or to introduce the second dopant into the solar cell substrate.

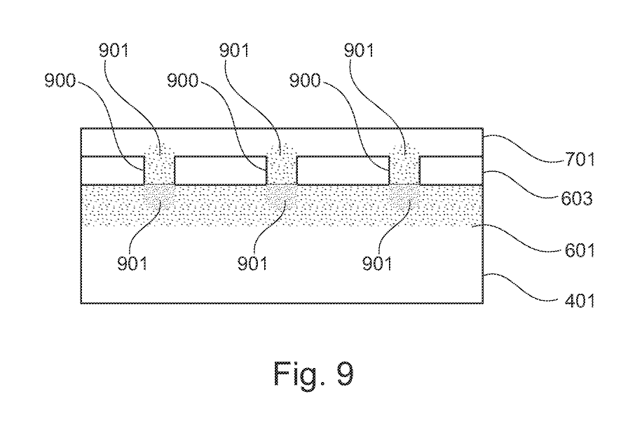

FIGS. 4 to 9 each show a schematic view of a solar cell substrate at various points in time of the method for manufacturing an emitter of a solar cell.

FIG. 4 shows a solar cell substrate 401 which in this context, by way of an example, is formed as a wafer. For example, a silicon wafer may be provided. On the wafer 401, a first dopant is deposited as a layer 403. The first dopant may e.g. be phosphorus.

According to FIG. 5, the deposited phosphorus layer 403 is driven into the wafer 401 by means of oxygen. The addition of oxygen is in this context schematically depicted in FIG. 5 by means of several arrows having the reference numeral 501.

FIG. 6 shows the wafer 401 which in a region below its surface comprises a region doped by the first dopant. This doped region is herein depicted in a dotted manner and denoted by the reference numeral 601.

Due to the fact that according to FIG. 5 the first dopant was driven into the wafer 401 by oxygen, whereby an oxide layer 603 was formed on the surface of the wafer 401 simultaneously with the driving-in of the first dopant. This oxide layer 603 is impenetrable, for a second dopant, in this context e.g. phosphorus.

FIG. 7 shows the doped wafer 401 with its oxide layer 603, wherein the second dopant, e.g. phosphorus, was deposited on the oxide layer 603 (layer 701). It may e.g. be provided that the oxide layer 603 may be charged with POCl₃ by adding oxygen in order to form phosphorus silicate glass on the oxide layer 603, so that phosphorus silicate glass is deposited on the oxide layer 603. The deposited phosphorus silicate glass layer 701 then preferably serves as a phosphorus source for further processing steps, as a diffusion source for laser processes. In this context, this additional source of a second dopant provides the formation of a region which may form a good contact resistance with regard to the doped region 601 by means of a sufficient concentration of dopants on the surface. Furthermore, by means of this process, solute phosphorus is provided on the surface of the wafer 401 which is, however, electrically inactive and thus only influences a contact formation.

In an exemplary manner, FIG. 8 shows how the wafer 401 may be processed further by means of a laser according to FIG. 7. The laser radiation of FIG. 8 is characterized by means of wavy arrows having the reference numeral 801. By means of charging the layer 701 of the second dopant, in this context e.g. a phosphorus silicate glass layer, with laser pulses or, respectively, with a continuous laser beam, phosphorus may diffuse into the wafer 401 or, respectively, the phosphorus may diffuse through the oxide layer 603 in order to electrically contact the doped region 601, i.e. the emitter.

FIG. 9 depicts the wafer 401 of FIG. 8 after processing with a laser. The oxide layer 603 was opened at several positions. Herein, these apertures are characterized by the reference numeral 900. Through these apertures 900, it was also possible to drive the second dopant into the wafer 401 by means of the laser pulses or, respectively, the continuous laser beam 801. The second dopant, in this case phosphorus, is schematically characterized by the reference numeral 901, the second dopant originating from the layer 701. Due to the doping by means of the first and the second dopant, the region in the wafer 401 below the apertures 900 thus comprises an increased concentration of dopants when compared to regions located outside of this area and merely doped with the first dopant. In these doubly doped regions below the apertures 900, a good electrical contacting or, respectively, a sufficiently good contact resistance of the emitter is thus provided.

In summary, the invention comprises the idea of providing a two-stage diffusion production method for an emitter, for a selective emitter, so that the steps of diffusing a first dopant, e.g. phosphorus, and providing a second dopant, e.g. phosphorus, for forming a good contact resistance are provided as separate steps. Thereby, on the one hand, a good contact resistance is formed, wherein the solar cell simultaneously comprises good quantum efficiency. The method for producing an emitter of a solar cell described herein may preferably also be used for standard diffusion processes, for one-stage diffusion processes.

According to an aspect, a method for producing an emitter of a solar cell is provided. In a first step, a first dopant, a first doping means or, respectively, a first doping material comprising the first dopant is introduced into a solar-cell substrate via a surface of the solar-cell substrate. Moreover, a diffusion barrier layer is formed on the surface of the solar-cell substrate, the diffusion barrier layer being impenetrable for a second doping means or, respectively, a second doping material comprising the second dopant. The second dopant is then arranged on said diffusion barrier layer.

According to a further aspect, a solar cell is provided which comprises an emitter, the emitter being manufactured by means of the method for producing an emitter of a solar cell.

By introducing a first dopant into a solar-cell substrate via a surface of the solar-cell substrate, the solar-cell substrate is doped. Thus, a layer arranged below the surface of the solar-cell substrate emerges into which the first dopant has been introduced. This doped layer forms an emitter of the solar cell.

A diffusion barrier layer is formed on the solar-cell substrate doped in such a way, the diffusion barrier layer being impenetrable for a second dopant. This means that the second dopant cannot diffuse through the diffusion barrier layer.

Thus, due to the fact that the diffusion barrier layer is impenetrable by the second dopant, a clearly defined amount of the second dopant may be arranged on the diffusion barrier layer for further processing steps after forming the diffusion barrier layer, without e.g. partial amounts of the second dopant arranged on the diffusion barrier layer inadvertently diffusing into the solar cell substrate in the process, which would usually result in the fact that they would no longer be available for the further processing steps.

A further aspect may comprise the forming of a contact for contacting the doped semiconductor substrate, for contacting the emitter. In this context, a clearly defined contact resistance may be achieved due to the clearly defined amount of the second dopant. Furthermore, this provides a sufficient amount of a second dopant for an electrical contacting.

According to a further aspect, an aperture, several apertures is/are formed in the diffusion barrier layer for introducing the second dopant into the solar cell substrate via the aperture. This means that it is possible to introduce the second dopant into the solar cell substrate through the aperture in the diffusion barrier layer in such a way as to allow for a doping of the solar cell substrate by means of a second dopant. In the region of the solar cell substrate which is arranged below the aperture of the diffusion barrier layer this causes a high concentration of dopants insofar as this region is doped by means of the first dopant as well as by means of the second dopant. As a result, a good contact resistance may be formed in this region in order to electrically contact the doped solar cell substrate, in this context the emitter.

The regions which are merely doped by the first dopant thus comprise a comparatively low doping concentration insofar as these regions are merely doped by the first dopant. This reduces a recombination probability of charge carriers, in this context of electrons and holes, which increases a quantum efficiency of the solar cell.

According to a further aspect, the diffusion barrier layer may be opened by means of a laser. Preferably, the second dopant may be introduced into the solar cell substrate by the laser. Opening the diffusion barrier layer by a laser or, respectively, introducing the second dopant by a laser means that the diffusion barrier layer or, respectively, the second dopant is charged with laser pulses and/or with a continuous laser beam.

According to a further aspect, the forming of the diffusion barrier layer comprises forming an oxide layer on the surface of the solar cell substrate. This means that an oxide layer is formed as a diffusion barrier layer on the surface of the solar cell substrate. It may preferably be provided that the surface is oxidized so that the oxidized surface of the solar cell substrate forms the diffusion barrier layer. Oxidizing the surface of the solar cell substrate may preferably be carried out by means of oxygen-charging of the surface, by gaseous oxygen.

According to a further aspect, the introduction of the first dopant may comprise driving the first dopant into the solar cell substrate by oxygen. For example, it may be provided that the first dopant or doping means or, respectively, doping material comprising the first dopant is arranged, deposited, on the surface of the solar cell substrate, the first dopant being driven through the surface into the solar cell substrate by means of oxygen.

According to a further aspect, it may be provided that an amount of oxygen measured in standard cubic centimetres per minute is increased by oxygen during driving in of the first dopant. In the following, standard cubic centimetres per minute shall be abbreviated to sccm. The unit standard cubic centimetres defines a defined flowing amount of gas, a number of particles or amount of gas, per unit of time. The standard cubic centimetre is a gas volume of V=1 cm³ under standard conditions, i.e. T=0° C. and P=1013.25 hPa, i.e. what is referred to as physical standard conditions according to DIN 1343. In this context, the standardized volume may be converted into a mass flow by multiplication with the associated standard density.

Thus, by increasing an amount of oxygen in standard cubic centimetres per minute, the diffusion barrier layer is formed as an oxide layer simultaneously with the driving in of the first dopant, i.e. the doping of the solar cell substrate by the first dopant, insofar as the addition of oxygen in an increased concentration oxidizes the surface of the solar cell substrate.

According to a further aspect, the solar cell substrate is p-doped and the first and second dopant are n-dopants. An n-dopant may be referred to as a donor.

According to a further aspect, it may be provided that the solar cell substrate is n-doped and the first and the second dopant are p-dopants. A p-dopant may be referred to as an acceptor.

Thus, by n-doping a p-doped solar cell substrate or, respectively, by p-doping an n-doped solar cell substrate, a space-charge region with a pn-junction is formed, the region of the solar cell substrate doped by means of the first dopant forms the emitter, preferably the selective emitter, of the solar cell.

According to a further aspect, the first dopant and the second dopant, the first doping material and the second doping material, may be identical. This simplifies the manufacturing process in an advantageous manner.

According to a further aspect, phosphorus silicate glass is deposited on the surface of the solar cell substrate as a first doping substance for introducing phosphorus as the first dopant. This means that phosphorus silicate glass is deposited on the surface of the solar cell substrate, the phosphorus contained in the phosphorus silicate glass being driven into the solar cell substrate by adding oxygen.

According to a further aspect, it may be provided that phosphorus silicate glass is deposited on the diffusion barrier layer, on the oxide layer, as a second dopant in order to arrange phosphorus as the second dopant. This means that phosphorus silicate glass is deposited on the diffusion barrier layer in order to arrange the phosphorus contained in the phosphorus silicate glass on the diffusion barrier layer as the second dopant.

According to a further aspect, a layer thickness of the deposited phosphorus silicate glass and/or a layer thickness of the oxide layer are respectively between 10 nm and 50 nm. Preferably, the individual layer thicknesses are configured in an identical or differing manner. This means that a layer thickness of the phosphorus silicate glass directly deposited on the surface of the solar cell substrate may be between 10 nm and 50 nm. A layer thickness of the diffusion barrier layer, of the oxide layer, may e.g. be between 10 nm and 50 nm. Preferably, the layer thickness of the phosphorus silicate glass deposited on the diffusion barrier layer, on the oxide layer, is between 10 nm and 50 nm. The above description concerning the individual layer thicknesses in context with phosphorus silicate glass or, respectively, the oxide layer generally apply to any first and second doping materials as well as to any diffusion barrier layers.

According to a further aspect, it may be provided that the phosphorus silicate glass is deposited on the surface of the solar cell substrate or, respectively, on the diffusion barrier layer, on the oxide layer, by means of phosphorus oxychloride (POCl) and oxygen. In addition to or instead of phosphorus oxychloride (POCl), POCl₃ may be used.

According to a further aspect, an amount of the phosphorus oxychloride or, respectively, POCl₃ may be between 500 sccm and 1500 sccm.

According to a further aspect, an amount of oxygen may be between 150 sccm and 5000 sccm. This means that an amount of oxygen which is e.g. used for the deposition of the phosphorus silicate glass and/or for the formation of the oxide layer is between 150 sccm and 5000 sccm.

According to a further aspect, it may be provided that at least in one of the steps of introducing the first dopant, of forming the diffusion barrier layer and of arranging the second dopant, a temperature between 780° C. and 860° C. is set. Preferably, it may be provided that the temperature is different or identical in the three steps. Preferably, it may be provided that the temperature is varied in at least one of the steps, in the region between 780° C. and 860° C.

According to a further aspect, it may be provided that a time duration of at least one of the steps of introducing the first dopant, of forming the diffusion barrier layer and of arranging the second dopant is between 5 and 20 minutes. It may be provided that a respective time duration of the individual steps is identical or different.

According to a further aspect, it may be provided that the solar cell substrate is a semiconductor substrate. The solar cell substrate may, for example, be a silicon substrate. The silicon substrate may, for example, be doped with boron and is thus positively conducting, for example, p-conducting. The solar cell substrate may be formed as a wafer.

What is claimed is:

1. A method of producing an emitter of a solar cell comprising:
introducing a first dopant into a solar cell substrate through a surface of the solar-cell substrate;
forming a diffusion barrier layer on the surface of the solar cell substrate which is impenetrable by a second dopant, and
arranging the second dopant on the diffusion barrier layer.

2. The method of claim 1, wherein an aperture is formed in the diffusion barrier layer for introducing the second dopant through the aperture into the solar cell substrate.

3. The method of claim 1, wherein forming the diffusion barrier layer comprises forming an oxide layer on the surface of the solar-cell substrate.

4. The method of claim 3, wherein introducing the first dopant comprises driving the first dopant into the solar cell substrate with oxygen.

5. The method of claim 4, wherein an amount of oxygen is increased during the driving in process by standard cubic centimetres per minute.

6. The method of claim 4, wherein an amount of oxygen is between 150 sccm and 5000 sccm.

7. The method of claim 1, wherein in during at least one of the steps of introducing the first dopant, of forming the diffusion barrier layer and of arranging the second dopant, a temperature between 780° C. and 860° C. is set.

8. The method of claim 1, wherein a duration of time of at least one of the steps of introducing the first dopant, of forming the diffusion barrier layer and of arranging the second dopant is between 5 minutes and 20 minutes.

9. The method of claim 1, wherein a layer thickness of the diffusion barrier layer is between 10 nm and 50 nm.

10. The method of claim 1, wherein the solar cell substrate has a p-doping and the first and the second dopant are n-dopants.

11. The method of claim 1, wherein the solar cell substrate has an n-doping and the first and the second dopant are p-dopants.

12. A method of producing an emitter of a solar cell comprising:
depositing phosphorus on a surface of a solar cell substrate;
introducing phosphorus into the solar cell substrate through the surface of the solar cell substrate with oxygen, said introducing with oxygen simultaneously comprising driving the phosphorus into the solar cell substrate with oxygen and forming a diffusion barrier layer on the surface of the solar cell substrate which is impenetrable by a second dopant, and
arranging the second dopant on the diffusion barrier layer.

13. The method of claim 12, wherein the phosphorus is deposited on the surface of the solar cell substrate in form of phosphorus silicate glass.

14. The method of claim 12, wherein phosphorus silicate glass is deposited on the diffusion barrier layer in order to arrange phosphorus as a second dopant.

15. The method of claim 13, wherein the phosphorus silicate glass is deposited by means of phosphorus oxychloride and oxygen, wherein an amount of phosphorus oxychloride is between 500 sccm and 1500 sccm and an amount of oxygen is between 150 sccm and 5000 sccm.

16. The method of claim 14, wherein the phosphorus silicate glass is deposited with of phosphorus oxychloride and oxygen, wherein an amount of phosphorus oxychloride is between 500 sccm and 1500 sccm and an amount of oxygen is between 150 sccm and 5000 sccm.

17. A solar cell comprising an emitter, said emitter comprising:
a first dopant introduced into a solar cell substrate through a surface of the solar cell substrate,
a diffusion barrier layer on the surface of the solar cell substrate which is impenetrable by a second dopant, and
the second dopant arranged on the diffusion barrier layer.

18. The solar cell of claim 19, wherein the first dopant is phosphorus, said phosphorus being deposited on the surface of the solar cell substrate in form of phosphorus silicate glass, being introduced into the solar cell substrate through the surface of the solar cell substrate by means of oxygen, said introducing by means of oxygen simultaneously comprising driving the phosphorus into the solar cell substrate by means of oxygen and forming the diffusion barrier layer on the surface of the solar cell substrate.

19. The solar cell of claim 19, wherein the second dopant is phosphorus, said phosphorus being deposited on the on the diffusion barrier layer in form of phosphorus silicate glass.
